(19) United States
(12) Patent Application Publication
(10) Pub. No.: US 2017/0181287 A1
(43) Pub. Date: Jun. 22, 2017

(54) ELECTRONIC PACKAGE

(71) Applicant: Siliconware Precision Industries Co., Ltd., Taichung (TW)

(72) Inventors: Jyun-Yuan Jhang, Taichung (TW); Ming-Fan Tsai, Taichung (TW); Ho-Chuan Lin, Tantzu (TW); Ying-Wei Lu, Tantzu (TW); Guang-Hwa Ma, Taichung (TW)

(21) Appl. No.: 15/064,016

(22) Filed: Mar. 8, 2016

(30) Foreign Application Priority Data
Dec. 22, 2015 (TW) 104143100

(51) Int. Cl. H05K 1/18; H05K 1/11; H05K 1/02

(52) U.S. Cl. CPC H05K 1/185; H05K 1/0216; H05K 1/115; H05K 2201/0723; H05K 2201/09209

(57) ABSTRACT

An electronic package is provided, which includes a substrate and an antenna board structure disposed on the substrate. The antenna board structure has a first portion, a second portion and a partition portion between the first portion and the second portion. As such, current can be split into two paths so as to spread electromagnetic radiation, and thus produce electromagnetic radiation with a high bandwidth.

### BACKGROUND

1. Technical Field

The present disclosure relates to electronic packages, and more particularly, to an electronic package having an antenna structure.

2. Description of Related Art

Along with the rapid development of electronic industries, electronic products are developed toward the trend of multi-function and high performance. Wireless communication technologies have been widely applied in various kinds of consumer electronic products for receiving or transmitting various wireless signals. To meet the miniaturization requirement of consumer electronic products, wireless communication modules are becoming lighter, thinner, shorter and smaller. For example, patch antennas have been widely applied in wireless communication modules of electronic products such as cell phones and personal digital assistants (PDAs) due to their advantages of small size, light weight and easy fabrication.

FIG. 1 is a schematic cross-sectional view of a conventional wireless communication module. Referring to FIG. 1, the wireless communication module 1 has: a substrate 10, an electronic element 11 disposed on and electrically connected to the substrate 10, an encapsulant 12 encapsulating the electronic element 11, and an antenna structure 13 disposed on the encapsulant 12. The antenna structure 13 has a support portion 130 disposed on the encapsulant 12, an extending portion 133 extending upward from the support portion 130, and an antenna portion 131 connected to the extending portion 133.

However, referring to FIG. 1′, since the antenna portion 131 of the conventional wireless communication module 1 is an integral rectangular board, the antenna portion 131 operates only at a low bandwidth of 2.4 to 5.8 GHz and cannot operate at a high bandwidth.

Further, electromagnetic radiation emitted from the antenna portion may adversely affect operation of other electronic elements and hence impair operation of the wireless communication module 1.

Therefore, how to overcome the above-described drawbacks has become critical.

### SUMMARY

In view of the above-described drawbacks, the present disclosure provides an electronic package, which comprises: a substrate; and an antenna board structure disposed on the substrate and having a first portion, a second portion and a partition portion between the first portion and the second portion.

In an embodiment, the partition portion is configured with an opening.

In an embodiment, the partition portion is made of a material different from those of the first portion and the second portion.

In an embodiment, the partition portion is disposed around an outer periphery of the first portion.

In an embodiment, the second portion is disposed around an outer periphery of the first portion.

In an embodiment, the electronic package further comprises a shielding structure disposed around a periphery of the antenna board structure. For example, the shielding structure has a post shape or a wall shape.

In an embodiment, the electronic package further comprises an electronic element disposed on the substrate.

In an embodiment, the electronic package further comprises an encapsulant formed on the substrate. For example, the antenna board structure is disposed on and in contact with the encapsulant. In an embodiment, the electronic package further comprises a shielding structure embedded in the encapsulant and disposed around a periphery of the antenna board structure. For example, the shielding structure has a post shape or a wall shape.

According to the present disclosure, the first portion and the second portion of the antenna board structure of the electronic package allow current to be split into two paths so as to spread electromagnetic radiation, thereby producing electromagnetic radiation with a high bandwidth.

Further, the shielding structure of the electronic package prevents electromagnetic radiation from adversely affecting operation of other electronic elements.

### BRIEF DESCRIPTION OF DRAWINGS

FIG. 1 is a schematic cross-sectional view of a conventional wireless communication module;

FIG. 1′ is a schematic partial upper view of FIG. 1;

FIG. 2 is a schematic perspective view of an electronic package according to a first embodiment of the present disclosure;

FIG. 3A is a schematic cross-sectional view of an electronic package according to a second embodiment of the present disclosure;

FIG. 3B is a schematic partial upper view of FIG. 3A;

FIG. 3C is a schematic perspective view of FIG. 3B;

FIG. 3C′ is a schematic perspective view showing another embodiment of FIG. 3C;

FIG. 4 is a schematic perspective view showing another embodiment of FIG. 2;

FIG. 5 is a schematic partial upper view of an electronic package according to a third embodiment of the present disclosure; and

FIG. 5′ is a schematic cross-sectional view showing another embodiment of FIG. 5.

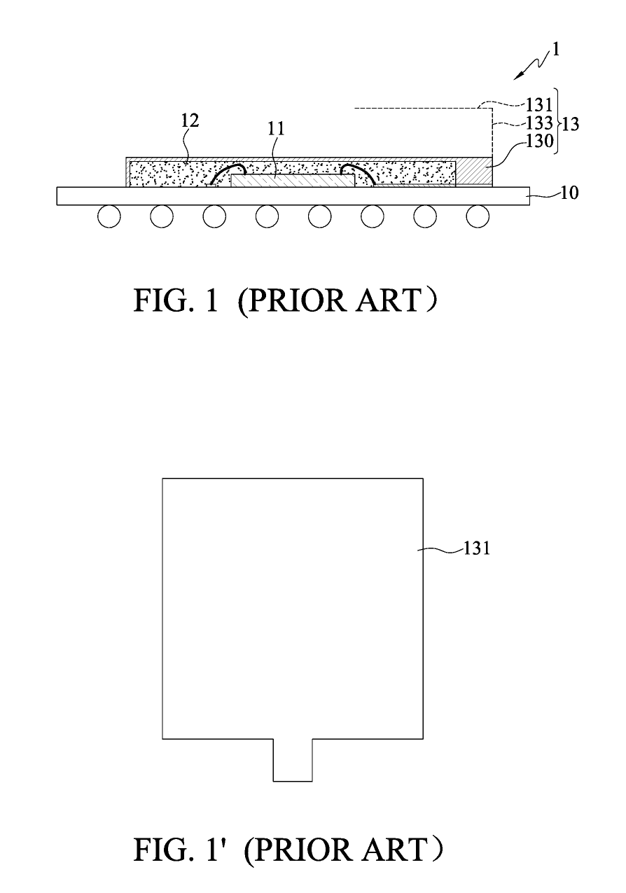

### DETAILED DESCRIPTION OF PREFERRED EMBODIMENTS

The following illustrative embodiments are provided to illustrate the disclosure of the present disclosure, these and other advantages and effects can be apparent to those in the art after reading this specification.

It should be noted that all the drawings are not intended to limit the present disclosure. Various modifications and variations can be made without departing from the spirit of the present disclosure. Further, terms such as “first”, “second”, “on”, “a” etc. are merely for illustrative purposes and should not be construed to limit the scope of the present disclosure.

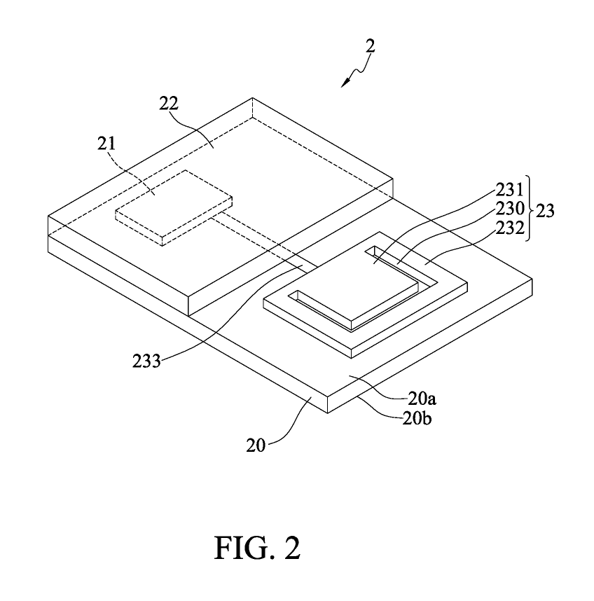

FIG. 2 is a schematic perspective view of an electronic package 2 according to a first embodiment of the present disclosure.

Referring to FIG. 2, the electronic package 2 is a SiP (system in package) wireless communication module. The electronic package 2 has a substrate 20, at least an electronic element 21 disposed on the substrate 20, an encapsulant 22 encapsulating the electronic element 21, and an antenna board structure 23 disposed on the substrate 20.

The substrate 20 is a circuit board or a ceramic board. The substrate 20 has a first surface 20a, a second surface 20b opposite to the first surface 20a, and a plurality of circuit layers (not shown) formed in the substrate 20.

The electronic element 21 is disposed on the first surface 20a of the substrate 20 and electrically connected to the circuit layers of the substrate 20.

The electronic element 21 can be an active element such as a semiconductor chip, a passive element such as a resistor, a capacitor or an inductor, or a combination thereof.

The encapsulant 22 is formed on the first surface 20a of the substrate 20 to encapsulate the electronic element 21.

In the present embodiment, the electronic element 21 is not exposed from the encapsulant 22, and the encapsulant 22 is made of polyimide, dry film, epoxy resin or molding compound.

The antenna board structure 23 is disposed in contact with the first surface 20a of the substrate 20. The antenna board structure 23 has a first portion 231, a second portion 232 and a partition portion 230 between the first portion 231 and the second portion 232.

In the present embodiment, the antenna board structure 23 is a rectangular metal board and the partition portion 230 is configured as an opening, for example, a slot.

Further, the second portion 232 (or the partition portion 230) is disposed around an outer periphery of the first portion 231. For example, the first portion 231 has a rectangular plate shape, the second portion 232 has a ring shape, and the first portion 231 and the second portion 232 meet at one side. In fabrication, a slot (i.e., the partition portion 230) is formed along three sides of a metal board, thereby forming the first portion 231 and the second portion 232.

Furthermore, the antenna board structure 23 has an extending portion 233 connected to the electronic element 21. For example, the extending portion 233 has one end connected to the meeting side of the first portion 231 and the second portion 232, and the other end connected to the electronic element 21.

In addition, the extending portion 233 is partially covered by the encapsulant 22, and the partition portion 230, the first portion 231 and the second portion 232 are exposed from the encapsulant 22.

The first portion 231 and the second portion 232 of the antenna board structure 23 of the electronic package 2 allow current to be split into two paths so as to spread electromagnetic radiation, thus producing electromagnetic radiation with a high bandwidth.

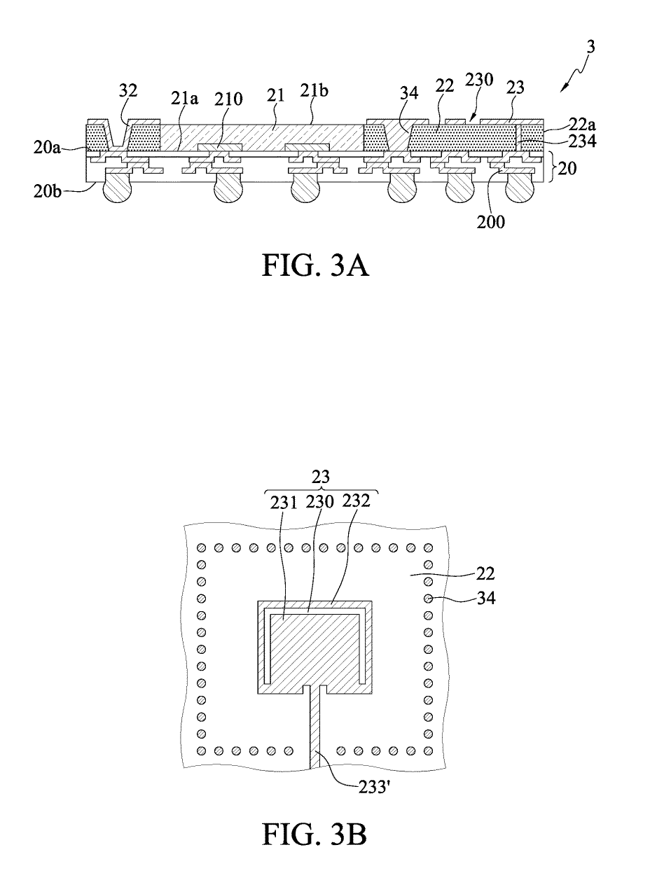

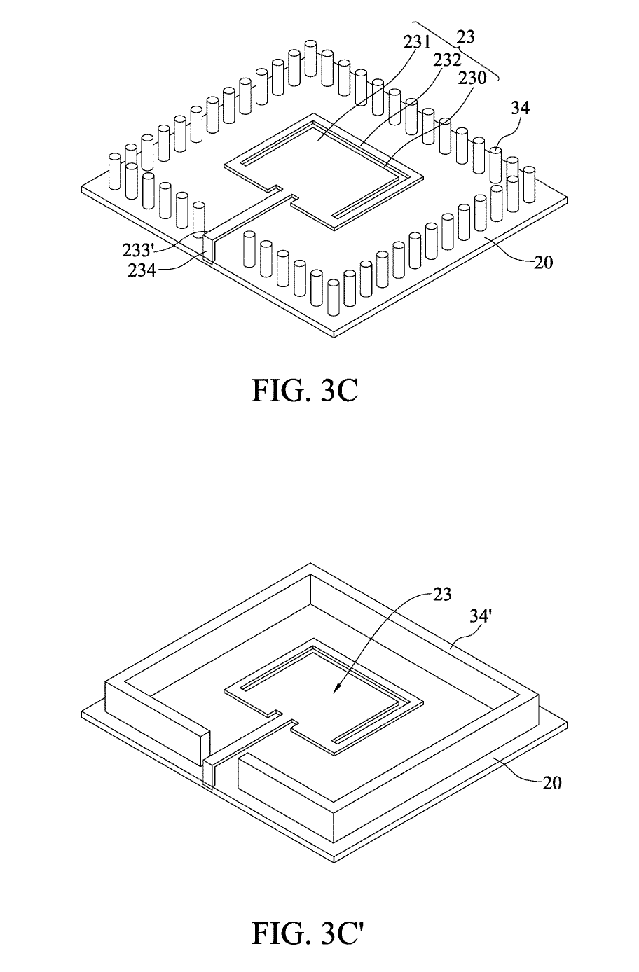

FIGS. 3A to 3C are schematic views of an electronic package 3 according to a second embodiment of the present disclosure. A main difference of the second embodiment from the first embodiment is the addition of a shielding structure.

Referring to FIG. 3A, the electronic package 3 has a substrate 20, an electronic element 21, an encapsulant 22, an antenna board structure 23, and a shielding structure 34.

The substrate 20 has a first surface 20a, a second surface 20b opposite to the first surface 20a, and a plurality of circuit layers 200 exposed from the first surface 20a and the second surface 20b.

The electronic element 21 is disposed on the first surface 20a of the substrate 20 and electrically connected to the circuit layers 200.

In the present embodiment, the electronic element 21 has an active surface 21a with a plurality of electrode pads 210 and an inactive surface 21b opposite to the active surface 21a, and the electronic element 21 is attached to the first surface 20a of the substrate 20 via the active surface 21a thereof so as to allow the electrode pads 210 of the electronic element 21 to be electrically connected to the circuit layers 200.

The encapsulant 22 is formed on the first surface 20a of the substrate 20 to encapsulate the electronic element 21.

In the present embodiment, the inactive surface 21b of the electronic element 21 is exposed from the encapsulant 22. Further, a plurality of conductive through holes 32 are formed in the encapsulant 22 and electrically connected to the circuit layers 200. As such, a plurality of conductive elements such as solder balls (not shown) can be electrically connected to the conductive through holes 32 for stacking of an electronic device such as a package, a substrate or a circuit board (not shown).

The antenna board structure 23 is disposed in contact with the encapsulant 22 and has a partition portion 230 exposed form the encapsulant 22, as shown in FIG. 3B.

In the present embodiment, the extending portion 233′ of the antenna board structure 23 has an extending portion 234 that downwardly extends through the encapsulant 22 and is connected to the substrate 20 or the circuit layers 200. As such, the extending portion 233′, 234 is not connected to the electronic element 21. For example, the extending portion 234 is positioned in the encapsulant 22. Alternatively, the extending portion 234 extends to the substrate 20 along an outer side surface 22a of the encapsulant 22.

The shielding structure 34 is disposed around a periphery of the antenna board structure 23, as shown in FIG. 3B.

In the present embodiment, referring to FIG. 3C, the shielding structure 34 consists of a plurality of solid conductive posts. The conductive posts are embedded in the encapsulant 22 and have one ends exposed from the encapsulant 22.

In another embodiment, referring to FIG. 3C′, the shielding structure 34′ consists of conductive walls, and the conductive walls are embedded in the encapsulant 22 and have a top surface exposed from the encapsulant 22.

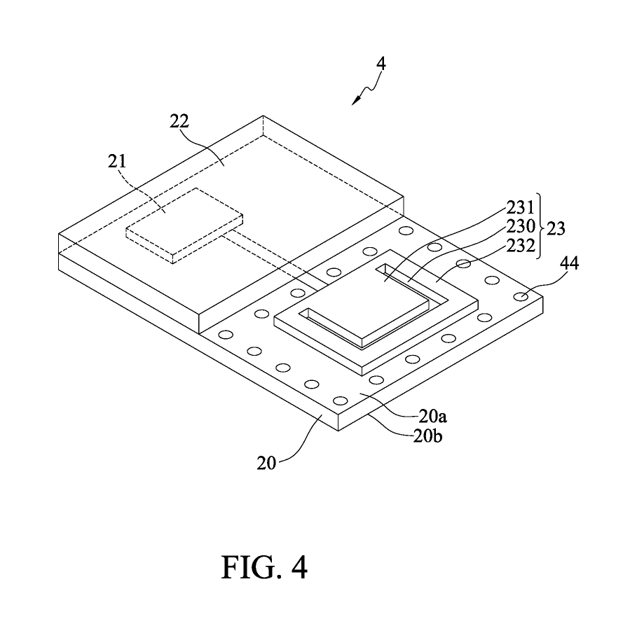

FIG. 4 shows a further embodiment continued from FIG. 2. Referring to FIG. 4, the electronic package 4 further has a shielding structure 44. The shielding structure 44 consists of conductive posts or conductive walls, which are embedded in the substrate 20 and have a surface exposed from the first surface 20a of the substrate 20.

The shielding structure 34, 34′, 44 of the electronic package 3, 4 is disposed around a periphery of the antenna board structure 23 to prevent electromagnetic radiation from adversely affecting operation of other electronic elements.

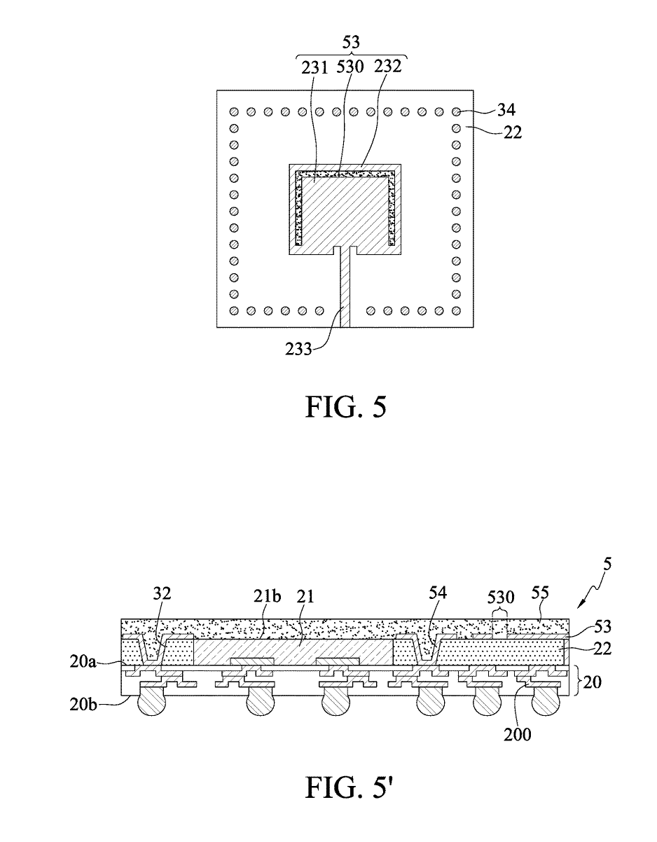

FIGS. 5 and 5′ are schematic views of an electronic package according to a third embodiment of the present disclosure. A main difference of the third embodiment from the second embodiment is the antenna board structure.

Referring to FIG. 5, the material of the partition portion 530 is different from that of the first portion 231 and the second portion 232. For example, the first portion 231 and the second portions 232 are made of a metal material and the partition portion 530 is made of an insulating material.

In another embodiment, referring to FIG. 5′, the electronic package 5 further has an insulating layer 55 formed on the encapsulant 22 for covering the inactive surface 21b of the electronic element 21, the antenna board structure 53 and the shielding structure 54. The shielding structure 54 consists of hollow conductive posts, i.e., vias, and the insulating layer 55 is filled in the opening of the antenna board structure 53 to form the partition portion 530.

According to the present disclosure, the first portion and the second portion of the antenna board structure of the electronic package allow current to be split into two paths so as to spread electromagnetic radiation, thus producing electromagnetic radiation with a high bandwidth.

Further, the shielding structure of the electronic package prevents electromagnetic radiation from adversely affecting operation of other electronic elements.

The above-described descriptions of the detailed embodiments are only to illustrate the preferred implementation according to the present disclosure, and it is not to limit the scope of the present disclosure. Accordingly, all modifications and variations completed by those with ordinary skill in the art should fall within the scope of present disclosure defined by the appended claims.

What is claimed is:

1. An electronic package, comprising:
a substrate; and
an antenna board structure disposed on the substrate and having a first portion, a second portion and a partition portion between the first portion and the second portion.

2. The electronic package of claim 1, wherein the partition portion is configured with an opening.

3. The electronic package of claim 1, wherein the partition portion is made of a material different from materials of the first portion and the second portion.

4. The electronic package of claim 1, wherein the partition portion is disposed around an outer periphery of the first portion.

5. The electronic package of claim 1, wherein the second portion is disposed around an outer periphery of the first portion.

6. The electronic package of claim 1, further comprising a shielding structure disposed around a periphery of the antenna board structure.

7. The electronic package of claim 6, wherein the shielding structure has a post shape or a wall shape.

8. The electronic package of claim 1, further comprising an electronic element disposed on the substrate.

9. The electronic package of claim 1, further comprising an encapsulant formed on the substrate.

10. The electronic package of claim 9, wherein the antenna board structure is disposed on and in contact with the encapsulant.

11. The electronic package of claim 9, further comprising a shielding structure embedded in the encapsulant and disposed around a periphery of the antenna board structure.

12. The electronic package of claim 11, wherein the shielding structure has a post shape or a wall shape.
